(19) United States
(12) Patent Application Publication
(10) Pub. No.: US 2026/0310837 A1
(43) Pub. Date: Oct. 8, 2026

(54) COMPUTER-IMPLEMENTED CAPACITY OPTIMIZATION METHOD FOR HYDRO-WIND-SOLAR INTEGRATED BASE CONSIDERING EXTREME CLIMATE EVENT RISKS

(71) Applicant: XIAN UNIVERSITY OF TECHNOLOGY, Xi'an City (CN)

(72) Inventors: Wei FANG, Xi'an City (CN); Jie ZHANG, Xi'an City (CN); Bo Ming, Xi'an City (CN); Qiang HUANG, Xi'an City (CN); Yi GUO, Xi'an City (CN); Xiangxiang JIANG, Xi'an City (CN); Shengce JIA, Xi'an City (CN); Jianan SHANG, Xi'an City (CN); Liangbo ZHANG, Xi'an City (CN); Xin XU, Xi'an City (CN)

(21) Appl. No.: 19/433,163

(22) Filed: Dec. 26, 2025

(30) Foreign Application Priority Data
Apr. 8, 2025 (CN) 202510433640X

(51) Int. Cl. G06F 30/13

(52) U.S. Cl. CPC G06F 30/13

(57) ABSTRACT

Disclosed is a computer-implemented capacity optimization method for a hydro-wind-solar integrated base considering extreme climate event risks, which includes: acquiring, by an acquisition device, a plurality of CMIP6 global climate model data and meteorological and hydrological historical data, where the CMIP6 global climate model data include historical climate model data and future climate model data; performing, by a correction device, bias correction on the future climate model data based on the historical climate model data and the meteorological and hydrological historical data to obtain corrected climate model data; predicting, by a prediction device, future hydro-wind-solar power output based on the corrected climate model data; determining, by a determination device, extreme climate events based on the corrected climate model data; determining, by the determination device, extreme climate event risks based on predicted long-series grid load and the future hydro-wind-solar power output during occurrence of the extreme climate events.

### CROSS-REFERENCE TO RELATED APPLICATIONS

This application claims priority to Chinese Patent Application No. 202510433640.X, filed on Apr. 8, 2025, which is incorporated herein by reference in its entirety.

### TECHNICAL FIELD

The present disclosure relates to the technical field of power system optimal dispatching, in particular to a computer-implemented capacity optimization method for a hydro-wind-solar integrated base considering extreme climate event risks.

### BACKGROUND

Global warming exerts an increasingly severe impact on human health and ecosystems. If greenhouse gas emissions such as carbon dioxide are not reduced, the global temperature is expected to rise by at least 4° C. by the end of the 21st century. As of 2023, the global average temperature has risen by approximately 1.45° C. compared to that at pre-industrial levels, which increasingly approaches the threshold set out in “The Paris Agreement”. The intensification of climate change impacts is driving the transition of the power system towards low-carbon and clean energy. Statistics from the National Energy Administration (NEA) show that as of the end of 2023, China's cumulative installed power generation capacity reached approximately 2.92 billion kilowatts (kW), with renewable energy accounting for more than 50% of the total cumulative installed capacity. In the future, renewable energy will play an increasingly important role in power systems, but renewable energy is vulnerable to changes in climate conditions. In addition to long-term changes in climate conditions, extreme climate events such as high temperatures, droughts, and cold waves caused by global warming have shown a trend of frequent occurrence, widespread occurrence, strong occurrence, and concurrent occurrence. Renewable energy power grids are facing dual challenges of surging power loads and insufficient power generation capacity, and the resulting extreme climate events will seriously restrict the stability and reliability of power grid operation.

As the dependence of power systems on climate conditions increases, the operational characteristics of the systems are gradually changing. For the development of renewable energy and the planning and construction of a hydro-wind-solar integrated base, the power security constraints caused by future extreme climate event risks need to be considered, and the optimal allocation of multi-objective power resource capacity is achieved under the premise of ensuring climate security. In recent years, considering the intermittent, fluctuating and random nature of wind-solar power generation, as well as the frequency and peak regulation characteristics of hydropower, domestic and foreign studies have focused on hydro-wind-solar integration, using the complementarity of resources and the rapid regulation capability of hydro turbine units to hedge against the fluctuations of new energy generation, forming high-quality and stable power sources, thereby meeting the requirements of grid for load stability.

However, traditional capacity optimal configuration methods for hydro-wind-solar integrated bases mostly carry out capacity optimal configuration based on historical power output data. Although historical data can reflect the operation in the past period, it cannot accurately predict the future power output change trend. In addition, traditional capacity configuration methods for multi-energy complementary systems do not fully consider the impact of climate change on system power output and capacity configuration. This makes the existing capacity configuration may not meet the requirements of stable system operation when facing extreme climate events, and there are certain risks.

Therefore, to improve the resilience of the hydro-wind-solar integrated bases under climate risks and promote the large-scale development of renewable energy, there is an urgent need for a capacity optimization method for a hydro-wind-solar integrated base considering extreme climate event risks.

### SUMMARY

To solve the above problems existing in the prior art, the present disclosure provides a computer-implemented capacity optimization method for a hydro-wind-solar integrated base considering extreme climate event risks, aiming to solve the technical problems in the design and implementation of renewable energy projects under complex climate conditions.

To achieve the above objective, the technical solution of the embodiment of the present disclosure is as follows:
in a first aspect, the present disclosure provides a computer-implemented capacity optimization method for a hydro-wind-solar integrated base considering extreme climate event risks, which includes:
acquiring a plurality of CMIP6 global climate model data and meteorological and hydrological historical data, where the CMIP6 global climate model data include historical climate model data and future climate model data;
performing bias correction on the future climate model data based on the historical climate model data and the meteorological and hydrological historical data to obtain corrected climate model data;
predicting future hydro-wind-solar power output based on the corrected climate model data;
determining extreme climate events based on the corrected climate model data;
determining extreme climate event risks based on predicted long-series grid load and the future hydro-wind-solar power output during occurrence of the extreme climate events;
constructing a multi-objective capacity optimal configuration model for the hydro-wind-solar integrated base considering extreme climate event risks with objectives of minimizing extreme climate event risks and maximizing life cycle benefit, and determining a multi-objective capacity optimal configuration strategy for the hydro-wind-solar integrated base based on the capacity optimal configuration model;
where a first objective function for minimizing the extreme climate event risks is:

$$min {f}_{1} = {\sum }_{i = 1}^{I} {M}_{i} \cdot ( {R}_{d} + {R}_{h} + … + {R}_{c} ) ;$$

where: I is a number of scenario modes; i is a period; Mᵢ is an occurrence frequency of the extreme climate events leading to reduced power output in the period i; R_{d}, Rₕ, . . . and R_{c} are probabilities of low power output operation of hydro-wind-solar power under different extreme climate event conditions respectively;
a second objective function for maximizing the life cycle benefit is:

$$max {f}_{2} = {\sum }_{t = 0}^{T} \frac{( {S}_{ele} + {S}_{subsidy} + {S}_{carbon} ) - ( {C}_{ope} + {C}_{main} + {C}_{sto} )}{{( 1 - r )}^{t}} - {I}_{o} ;$$

where: t is a period; T is a project life cycle; r is a discount rate; Sₑₗₑ is an electricity sales revenue; S_{subsidy} is a government subsidy revenue; S_{carbon} is a carbon trading revenue; Cₒₚₑ is a cost for power station operation; Cₘₐᵢₙ is a cost for power station facility maintenance; Cₛₜₒ is a cost for an energy storage system; and Iₒ is a cost for wind-solar-hydro storage integrated construction.

In a second aspect, an embodiment of the present disclosure provides an electronic device, including: a memory, used for storing executable instructions; a processor, used for executing the executable instructions stored in the memory to implement the above computer-implemented capacity optimization method for a hydro-wind-solar integrated base considering extreme climate event risks.

In a third aspect, an embodiment of the present disclosure provides a computer-readable storage medium storing executable instructions for, when executing the executable instructions, causing a processor to implement the above computer-implemented capacity optimization method for a hydro-wind-solar integrated base considering extreme climate event risks.

According to the computer-implemented capacity optimization method for a hydro-wind-solar integrated base considering extreme climate event risks provided by the present disclosure, first, acquiring a plurality of CMIP6 global climate model data and meteorological and hydrological historical data; performing bias correction on the future climate model data based on the historical climate model data and the meteorological and hydrological historical data to obtain corrected climate model data; predicting future hydro-wind-solar power output based on the corrected climate model data; determining extreme climate events based on the corrected climate model data; determining extreme climate event risks based on predicted long-series grid load and the future hydro-wind-solar power output during occurrence of the extreme climate events; and constructing a multi-objective capacity optimal configuration model for the hydro-wind-solar integrated base considering extreme climate event risks with objectives of minimizing extreme climate event risks and maximizing life cycle benefit, and determining a multi-objective capacity optimal configuration strategy for the hydro-wind-solar integrated base based on the capacity optimal configuration model. As such, in the present disclosure, in a first aspect, it is reliable that the hydro-wind-solar power output data is calculated from the future meteorological element data after bias correction, which can more accurately predict the future power output change trend; in a second aspect, considering extreme climate event risks in the capacity optimal configuration process improves the resilience of the power system under various climate conditions and ensures the normal operation of the power system; in a third aspect, the capacity optimal configuration method for a hydro-wind-solar integrated base can maximize the benefits of stakeholders while ensuring the safe and stable operation of the power system for different stakeholders such as power grids and power generation enterprise; in a fourth aspect, in the present disclosure, a multi-objective optimization model is used, comprehensively considering the impact of future extreme climate event risks and life cycle benefits, and achieving optimization of capacity configuration of the hydro-wind-solar integrated base. In addition, the solution of the present disclosure is applicable to the capacity configuration problems of the hydro-wind-solar integrated bases under different geographical locations and different climatic conditions, and has strong universality.

### BRIEF DESCRIPTION OF THE DRAWINGS

FIG. 1 is a structural schematic diagram of a capacity optimization system for a hydro-wind-solar integrated base considering extreme climate event risks according to an embodiment of the present disclosure;

FIG. 2 is a flow schematic diagram of a computer-implemented capacity optimization method for a hydro-wind-solar integrated base considering extreme climate event risks according to an embodiment of the present disclosure;

FIG. 3 is a flow schematic diagram of a computer-implemented capacity optimization method for a hydro-wind-solar integrated base considering extreme climate event risks according to an embodiment of the present disclosure; and

FIG. 4 is a structural schematic diagram of a composition of a capacity optimization device for a hydro-wind-solar integrated base considering extreme climate event risks according to an embodiment of the present disclosure.

### DETAILED DESCRIPTION

To make objectives, technical solutions and advantages of the present disclosure clearer, the present disclosure will be described in further detail below with reference to the accompanying drawings. The described embodiments should not be considered as limiting the present disclosure, and all other embodiments obtained by a person skilled in the art without making creative efforts shall fall within the protection scope of the present disclosure.

In the following description, reference is made to “some embodiments”, which describe a subset of all possible embodiments, but it can be understood that “some embodiments” can be the same subset or different subsets of all possible embodiments, and can be combined with each other without conflict. Unless otherwise defined, all technical and scientific terms used in the embodiments of the present disclosure have the same meanings as commonly understood by a person skilled in the technical field to which the embodiments of the present disclosure belong. The terms used in the embodiments of the present disclosure are only for the purpose of describing the embodiments of the present disclosure, and are not intended to limit the present disclosure.

The following describes an exemplary application of the capacity optimization device for a hydro-wind-solar integrated base considering extreme climate event risks according to the embodiment of the present disclosure. The capacity optimization device for a hydro-wind-solar integrated base considering extreme climate event risks provided by the embodiment of the present disclosure can be implemented as a terminal or a server. In an implementation, the capacity optimization device for a hydro-wind-solar integrated base considering extreme climate event risks provided by the embodiment of the present disclosure can be implemented as various types of terminals such as notebook computers, tablet computers, desktop computers, and mobile devices; in another implementation, the capacity optimization device for a hydro-wind-solar integrated base considering extreme climate event risks provided by the embodiment of the present disclosure can also be implemented as a server, where the server can be an independent physical server, a server cluster or a distributed system composed of a plurality of physical servers, or a cloud server that provides basic cloud computing services such as cloud services, cloud databases, cloud computing, cloud functions, cloud storage, network services, cloud communications, middleware services, domain name services, security services, Content Delivery Networks (CDN), and big data and artificial intelligence platforms. The terminal and the server can be directly or indirectly connected through wired or wireless communication, which is not limited in the embodiments of the present disclosure. The following describes an exemplary application when the capacity optimization device for a hydro-wind-solar integrated base considering extreme climate event risks is a server.

Traditional capacity optimization methods for hydro-wind-solar integrated bases are used relying on historical data, cannot accurately predict future power output changes, and do not fully consider extreme climate event risks, resulting in insufficient stability of the power system under extreme climates. The present disclosure realizes the accuracy and risk resistance of capacity configuration by means of a computer-executed method, using corrected climate data to predict future power output, quantifying extreme climate event risks, and constructing a multi-objective optimization model.

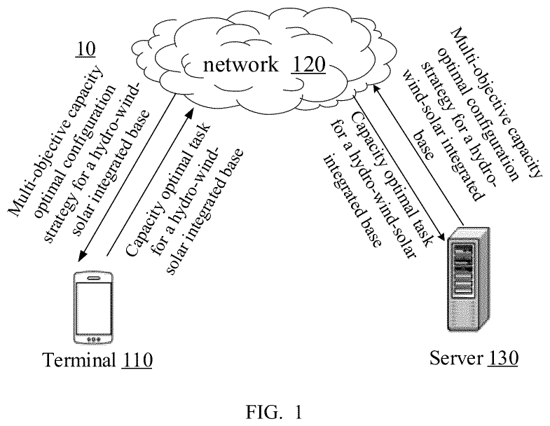

Referring to FIG. 1, FIG. 1 is a structural schematic diagram of a capacity optimization system 10 for a hydro-wind-solar integrated base considering extreme climate event risks according to an embodiment of the present disclosure. To realize the capacity optimization for the hydro-wind-solar integrated base considering extreme climate event risks, an embodiment of the present disclosure can provide a capacity optimization platform for a hydro-wind-solar integrated base considering extreme climate event risks, which can be implemented as a capacity optimization application for a hydro-wind-solar integrated base considering extreme climate event risks. A capacity optimization system 100 for a hydro-wind-solar integrated base considering extreme climate event risks provided by an embodiment of the present disclosure includes a terminal 110, a network 120 and a server 130, where the server 130 is a server of the capacity optimization application for a hydro-wind-solar integrated base considering extreme climate event risks. The server 130 can constitute the capacity optimization device for a hydro-wind-solar integrated base considering extreme climate event risks according to the embodiment of the present disclosure. The terminal 110 is connected to the server 130 through the network 120, and the network 120 can be a wide area network, a local area network, or a combination thereof.

In some embodiments, please refer to FIG. 1. When performing capacity optimal configuration for a hydro-wind-solar integrated base, the terminal 110 sends a capacity optimization task of the hydro-wind-solar integrated base to the server 130 through the network 120. In response to the capacity optimization task of the hydro-wind-solar integrated base initiated by the terminal 110, the server 130 acquires a plurality of CMIP6 global climate model data and meteorological and hydrological historical data through an acquisition device; performs bias correction on the future climate model data based on the historical climate model data and the meteorological and hydrological historical data by a correction device to obtain corrected climate model data; predicts future hydro-wind-solar power output based on the corrected climate model by a prediction device; calculates extreme climate events based on the corrected climate model data by a determination device; determines extreme climate event risks based on the predicted long-series grid load and the future hydro-wind-solar power output during the occurrence of extreme climate events through the determination device; constructs a multi-objective capacity optimal configuration model for a hydro-wind-solar integrated base considering extreme climate event risks with objectives of minimizing power generation fluctuations caused by extreme climate events and maximizing life cycle benefits through the determination device, and determines the multi-objective capacity optimal configuration strategy for the hydro-wind-solar integrated base based on the capacity optimal configuration model. After obtaining the multi-objective capacity optimal configuration strategy for the hydro-wind-solar integrated base, the server 130 sends the multi-objective capacity optimal configuration strategy for the hydro-wind-solar integrated base to the terminal 110 through the network 120.

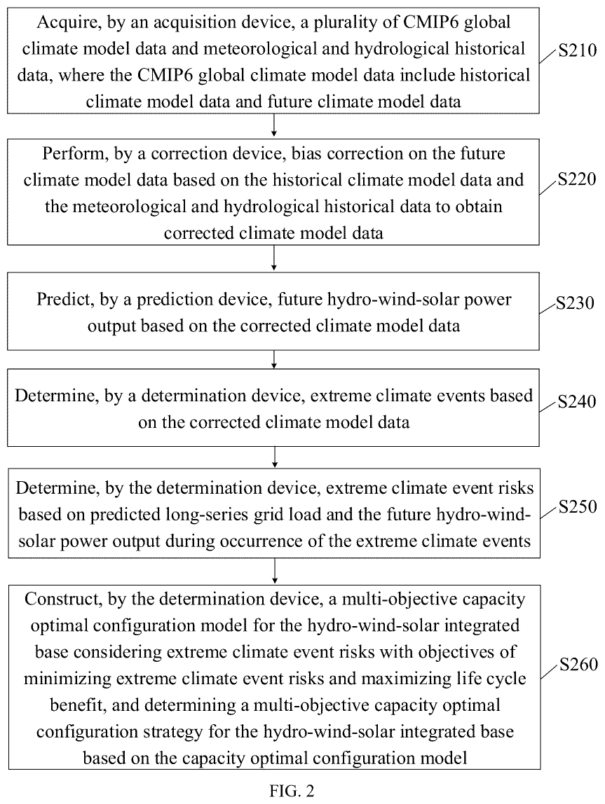

An embodiment of the present disclosure provides a computer-implemented capacity optimization method for a hydro-wind-solar integrated base considering extreme climate event risks. Referring to FIG. 2, FIG. 2 is a flow schematic diagram of a capacity optimization method for a hydro-wind-solar integrated base considering extreme climate event risks according to an embodiment of the present disclosure, which will be described in conjunction with the steps shown in FIG. 2.

Step S210 Acquire, by an acquisition device, a plurality of CMIP6 global climate model data and meteorological and hydrological historical data, where the CMIP6 global climate model data include historical climate model data and future climate model data.

It should be noted that Coupled Model Intercomparison Project Phase 6 (CMIP6) is the sixth phase of a global climate model intercomparison project, organized by the World Climate Research Programme. CMIP6 provides historical and future climate simulation data from a plurality of global climate models for studying climate change and its impacts. These data include meteorological elements such as temperature, precipitation, wind speed, and solar radiation, covering a global range with a time span from historical periods to different future climate scenarios.

In the present disclosure, the plurality of CMIP6 global climate model data can be a plurality of sets of data from different global scientific research institutions (such as Beijing Climate Center (BCC), Centre National de Recherches Météorologiques (CNRM), Environment and Climate Change Canada (EC), Goddard Institute for Space Studies (GISS), Institute of Numerical Mathematics (INM), Model for Interdisciplinary Research on Climate (MIROC), etc.).

In the embodiment of the present disclosure, the acquisition device uses CMIP6 data, which can provide a reliable climate change background for the capacity optimization of the hydro-wind-solar integrated base. By using a plurality of CMIP6 model data, uncertainty of a single model can be reduced, and the accuracy of prediction can be improved.

In some embodiments, meteorological and hydrological historical data refers to recorded meteorological and hydrological observation data over a past period, including precipitation, temperature, wind speed, runoff, reservoir water level, etc. These data are usually collected by observation equipment such as meteorological stations and hydrological stations, and undergo quality control and processing.

In the embodiment of the present disclosure, meteorological and hydrological historical data is the basis for correcting future climate model data, which can help eliminate systematic biases in climate models and ensure the accuracy of future climate predictions.

The acquisition device may specifically be a network interface device, such as a Network Interface Card (NIC), a modem or a wireless communication module, for accessing external databases (such as CMIP6 data servers, meteorological and hydrological data platforms) from the Internet or internal networks. Data storage devices, such as hard disk drives, solid-state drives or network-attached storage, for caching or storing the acquired data. Data collection device, such as meteorological sensors or hydrological monitoring equipment, and the acquisition device mainly extracts data from these systems through software interfaces (such as APIs).

Step S220 Perform, by a correction device, bias correction on the future climate model data based on the historical climate model data and the meteorological and hydrological historical data to obtain corrected climate model data.

In some embodiments, bias correction refers to comparing future climate model data with historical observation data to eliminate systematic biases in climate models, making future climate predictions more realistic. Here, the bias correction methods include at least linear scaling, quantile mapping, etc. Through bias correction, the reliability of climate data is improved, providing accurate input for subsequent power output prediction.

The correction device may specifically be a Central Processing Unit (CPU), a general computing core, for executing correction algorithms. Memory, such as Random Access Memory (RAM), for temporarily storing historical data, correction models and intermediate results. Dedicated computing hardware, such as Field-Programmable Gate Arrays (FPGAs) or Application-Specific Integrated Circuits (ASICs), for efficiently implementing specific correction algorithms.

Step S230 Predict, by a prediction device, future hydro-wind-solar power output based on the corrected climate model data.

In some embodiments, future hydropower output, future wind power output, and future solar power output are respectively predicted based on corresponding hydropower output prediction models, wind power output prediction models, and solar power output prediction models. Through power output prediction, the power generation potential of renewable energy can be understood in advance, and capacity configuration can be optimized.

The prediction device may specifically be a CPU for running complex power output prediction models (such as wind power output models, photovoltaic power output models, hydropower models). Memory, for storing model parameters, corrected data and prediction results. Mathematical coprocessors, such as floating-point units, for accelerating scientific computing. Cloud servers or edge computing devices, prediction requires distributed computing and is deployed on cloud platforms or local servers.

Step S240 Determine, by a determination device, extreme climate events based on the corrected climate model data.

In some embodiments, different types of extreme climate events refer to extreme climates such as high temperature, drought and cold wave. By determining extreme climate events, potential risks are identified, and the early warning capability of the system is enhanced.

The determination device may specifically be a CPU for executing risk calculation, optimization algorithms (such as Non-dominated Sorting Genetic Algorithm II (NSGA-II)) and model construction. Memory for storing risk indicators, optimization models and constraint conditions. Dedicated optimization hardware, such as acceleration cards for linear programming or integer programming, and can also be implemented through software libraries (such as MATLAB, Python's SciPy).

Step S250 Determine, by the determination device, extreme climate event risks based on predicted long-series grid load and the future hydro-wind-solar power output during occurrence of the extreme climate events.

In some embodiments, the server's predicted long-series grid load refers to the grid load predicted by a linear trend method.

In some embodiments, the server's extreme climate event risk refers to the ratio of the grid load loss duration during the occurrence of an extreme climate event to the total duration of the extreme climate event.

In some embodiments, the server can determine extreme climate events through an extreme climate event risk assessment model, where the extreme climate event risk assessment model is a mathematical model established based on historical climate model data, meteorological and hydrological historical data, and different types of extreme climate events for assessing extreme climate event risks. This model usually includes parameters such as the occurrence probability and impact degree of extreme climate events. Through risk assessment, the impact of extreme events is quantified, providing risk constraints for optimal configuration.

Step S260 Construct, by the determination device, a multi-objective capacity optimal configuration model for the hydro-wind-solar integrated base considering extreme climate event risks with objectives of minimizing extreme climate event risks and maximizing life cycle benefit, and determining a multi-objective capacity optimal configuration strategy for the hydro-wind-solar integrated base based on the capacity optimal configuration model.

Here, a first objective function for minimizing the extreme climate event risks is:

$$min {f}_{1} = {\sum }_{i = 1}^{I} {M}_{i} \cdot ( {R}_{d} + {R}_{h} + … + {R}_{c} ) ;$$

where: I is a number of scenario modes; i is a period; Mᵢ is an occurrence frequency of the extreme climate events leading to reduced power output in the period i; R_{d}, Rₕ, . . . and R_{c} are probabilities of low power output operation of hydro-wind-solar power under different extreme climate event conditions respectively. The first objective function improves the stability of the system by minimizing risks.

Here, a second objective function for maximizing the life cycle benefit is:

$$max {f}_{2} = {\sum }_{t = 0}^{T} \frac{( {S}_{ele} + {S}_{subsidy} + {S}_{carbon} ) - ( {C}_{ope} + {C}_{main} + {C}_{sto} )}{{( 1 + r )}^{t}} - {I}_{o} ;$$

where: t is a period; T is a project life cycle; r is a discount rate; Sₑₗₑ is an electricity sales revenue; S_{subsidy} is a government subsidy revenue; S_{carbon} is a carbon trading revenue; Cₒₚₑ is a cost for power station operation; Cₘₐᵢₙ is a cost for power station facility maintenance; Cₛₜₒ is a cost for an energy storage system; and Iₒ is a cost for wind-solar-hydro storage integrated construction. The second objective function ensures the economic feasibility of the project by maximizing benefits.

In some embodiments, the multi-objective capacity optimal configuration model for a hydro-wind-solar integrated base is a mathematical model established with objectives of minimizing extreme climate event risks and maximizing life cycle benefits. This model realizes the economy and reliability of the power system by optimizing the capacity configuration of hydro, wind, solar and energy storage.

In some embodiments, the first objective function aims to minimize extreme climate event risks and ensure the stability of the power system. This function quantifies the impact of power generation fluctuations by considering power generation output fluctuations under different extreme climate event scenarios.

In the present disclosure, the first objective function can effectively reduce the impact of extreme climate events on the power system and improve the risk resistance of the system.

In some embodiments, the second objective function aims to maximize the life cycle benefits of the hydro-wind-solar integrated base, including electricity sales revenue, government subsidy revenue, carbon trading revenue, etc., while considering cost for power station operations, maintenance costs, energy storage system costs and facility construction costs.

In the present disclosure, the second objective function can ensure the economic feasibility of the hydro-wind-solar integrated base, while also considering environmental and social benefits.

According to the computer-implemented capacity optimization method for a hydro-wind-solar integrated base considering extreme climate event risks provided by the present disclosure, first, acquiring, by a processor in a server, a plurality of CMIP6 global climate model data and meteorological and hydrological historical data; performing bias correction on the future climate model data based on the historical climate model data and the meteorological and hydrological historical data to obtain corrected climate model data; predicting future hydro-wind-solar power output based on the corrected climate model data; determining extreme climate events based on the corrected climate model data; determining extreme climate event risks based on predicted long-series grid load and the future hydro-wind-solar power output during occurrence of the extreme climate events; and constructing a multi-objective capacity optimal configuration model for the hydro-wind-solar integrated base considering extreme climate event risks with objectives of minimizing extreme climate event risks and maximizing life cycle benefit, and determining a multi-objective capacity optimal configuration strategy for the hydro-wind-solar integrated base based on the capacity optimal configuration model. As such, in the present disclosure, in a first aspect, it is reliable that the hydro-wind-solar power output data is calculated from the future meteorological element data after bias correction, which can more accurately predict the future power output change trend; in a second aspect, considering extreme climate event risks in the capacity optimal configuration process improves the resilience of the power system under various climate conditions and ensures the normal operation of the power system; in a third aspect, the capacity optimal configuration method for a hydro-wind-solar integrated base can maximize the benefits of stakeholders while ensuring the safe and stable operation of the power system for different stakeholders such as power grids and power generation enterprise; in a fourth aspect, in the present disclosure, a multi-objective optimization model is used, comprehensively considering the impact of future extreme climate event risks and life cycle benefits, and achieving optimization of capacity configuration of the hydro-wind-solar integrated base. In addition, the solution of the present disclosure is applicable to the capacity configuration problems of the hydro-wind-solar integrated bases under different geographical locations and different climatic conditions, and has strong universality.

In some embodiments, the above step S220 can be implemented through the following steps S221 to S222:
step S221 Perform data comparison between the historical climate model data and the meteorological and hydrological historical data to obtain meteorological data differences.
Step S222 Perform bias correction on the future climate model data using a quantile mapping method based on the meteorological data differences to obtain the corrected climate model data. Through the quantile mapping method, the accuracy and reliability of data correction are further improved.

In some embodiments, the corrected climate model data includes target wind speed, target temperature, target solar radiation and target precipitation; the above step S230 can be implemented through the following steps S231 to S233:
step S231 Predict future wind power output using a preset wind power output prediction model based on the target wind speed.
Step S232 Predict future solar power output using a preset photovoltaic power output prediction model based on the target temperature and the target solar radiation.
Step S233 Predict watershed runoff based on the target precipitation and a preset monthly water balance model; and predicting future hydropower output using a preset hydropower output prediction model based on the watershed runoff.

Here, the preset wind power output prediction model is:

$${P}_{i}^{w} = \{ \begin{matrix}0 , & {v}_{hub , i} \leq {v}_{i n} , {v}_{hub , i} \geq {v}_{i n} \\ \frac{θ}{{v}_{r}^{3} - {v}_{i n}^{3}} {v}_{hub , i}^{3} - \frac{θ}{{v}_{r}^{3} - {v}_{i n}^{3}} {v}_{i n}^{3} , & {v}_{i n} < {v}_{hub , i} < {v}_{r} \\ θ , & {v}_{r} < {v}_{hub , i} < {v}_{out}\end{matrix} ;$$

where

$${P}_{i}^{w}$$

is a wind power output in the period i; θ is installed capacity of a wind farm; v_{hub,j} is a wind speed at a wind turbine in the period i; and vᵢₙ, vₒᵤₜ, and vᵣ are cut-in wind speed, cut-out wind speed and rated wind speed of the wind turbine respectively.

In the embodiment of the present disclosure, the preset wind power output prediction model considers cut-in wind speed, cut-out wind speed and rated wind speed of the wind turbine, and can more accurately reflect a power output situation of a wind farm under different wind speed conditions. Especially under extreme wind speed conditions, the model can effectively predict power output fluctuation of the wind farm and provide a reliable basis for capacity optimization.

Here, the preset photovoltaic power output prediction model is:

$${P}_{i}^{s} = χ ( \frac{{R}_{i}^{s}}{{R}_{stc}^{s}} ) [ 1 + {α}_{p} ( {T}_{i} - {T}_{stc} ) ] ;$$

where

$${P}_{i}^{s}$$

is an actual photovoltaic average power output in the ith period; χ is installed capacity of a photovoltaic power station;

$${R}_{i}^{s}$$

is solar radiation intensity in the ith period;

$${R}_{stc}^{s}$$

is solar radiation intensity under standard test conditions; Tᵢ is solar panel temperature; T_{stc} is temperature under the standard test conditions; and αₚ is a temperature power conversion coefficient.

In the embodiment of the present disclosure, the preset photovoltaic power output prediction model not only considers the solar radiation intensity, but also introduces the solar panel temperature and temperature power conversion coefficient, which can more accurately reflect the actual power output situation of the photovoltaic power station. Especially under extreme climate conditions of high temperature or low temperature, the model can effectively predict the change of photovoltaic power output.

Here, the preset monthly water balance model is:

$${Q}_{n} = ( {S}_{n - 1} + {P}_{n} - {E}_{n} ) tanh ( \frac{{S}_{n - 1} + {P}_{n} - {E}_{n}}{SC} ) ;$$

where Qₙ is runoff in an nth month; Sₙ₋₁ is a soil moisture content at an end of a previous month; Pₙ is precipitation in the nth month; Eₙ is actual evaporation in the nth month; and SC is a maximum water storage capacity of watershed.

In the embodiment of the present disclosure, the preset monthly water balance model can more accurately predict watershed runoff by considering the soil moisture content at the end of the previous month, precipitation and actual evaporation. Especially under extreme climate conditions of drought or flood, the model can effectively reflect the change of runoff, thereby improving the prediction accuracy of hydropower output.

Here, the preset hydropower output prediction model is: N=9.81−ηQₙH; where η is an efficiency coefficient of a hydropower station; and H is a net water head of the hydropower station.

In some embodiments, the above step S240 can be implemented through the following steps S241 to S242:
step S241 Determine wind speed threshold, temperature threshold, solar radiation threshold and precipitation threshold based on the target wind speed, the target temperature, the target solar radiation and the target precipitation.
Step S242 Determine the extreme climate events based on the wind speed threshold, the temperature threshold, the solar radiation threshold and the precipitation threshold. By setting threshold, extreme events are accurately identified, and the sensitivity of the method is improved.

In some embodiments, the above method further includes: the occurrence frequency and the duration of the extreme climate events are calculated. Based on the foregoing embodiments, the above step S250 can also be implemented in the following manner:
the extreme climate event risks are determined based on the occurrence frequency, the duration, the predicted long-series grid load and the future hydro-wind-solar power output.

In the present disclosure, the occurrence frequency and duration of extreme climate events refer to the number of occurrences and the duration of each extreme climate event such as drought, high temperature, and cold wave under future climate conditions. These parameters are important indicators for evaluating extreme climate event risk.

In the present disclosure, the occurrence frequency and duration of extreme climate events can be counted to provide data support for extreme climate event risk assessment.

Here, the calculation formula of the occurrence frequency is:

$$F = {\sum }_{a = 1}^{I} A ( a ) , A ( a ) = \{ \begin{matrix}1 , S ( a ) \geq {S}_{m} OR S ( a ) < {S}_{n} \\ 0 , {S}_{n} \leq S ( a ) < {S}_{m}\end{matrix} ;$$

where A(a) is a number of occurrences of the extreme climate events meeting a corresponding threshold within a corresponding period; 1 is a total statistical duration; S(a) is an actual value of the target wind speed, the target temperature, the target solar radiation or the target precipitation at time a; Sₘ is an upper limit value for judging whether a current climate at time a is the extreme climate event; Sₙ is a lower limit value for judging whether the current climate at time a is the extreme climate event; and F is the occurrence frequency of the corresponding extreme climate event.

Here, the calculation formula of the duration is: Uₖ=a₂(k)−a₁(k); where Uₖ is a duration of a kth extreme climate event; a₁(k) is a start time of the kth extreme climate event; a₂(k) is an end time of the kth extreme climate event.

In some embodiments, constraint conditions for the first objective function and the second objective function are constructed. The constraint conditions include:
wind power output constraint:

$$0 \leq {P}_{i}^{w} \leq {P}_{m ax}^{w} ;$$

where

$${P}_{i}^{w}$$

is the wind power output in the period i; and

$${P}_{m ax}^{w}$$

is an upper limit value of the wind power output.

Solar power output constraint:

$$0 \leq {P}_{i}^{s} \leq {P}_{m ax}^{s} ;$$

where is

$${P}_{i}^{s}$$

the solar power output in the period i; and

$${P}_{max}^{s}$$

is an upper limit value of the solar power output.

Curtailment rate constraint: E_{ws}/E<σ; where E is a total wind-solar power generation in the period; E_{ws} is a total curtailed wind-solar power in the period; and σ is an allowable wind-solar curtailment rate of the system.

Hydropower station power output constraint:

$${P}_{min}^{h} \leq {P}_{i}^{h} \leq {P}_{max}^{h} ,$$

where

$${P}_{i}^{h}$$

is a hydropower output in the period i; and

$${P}_{min}^{h} and {P}_{max}^{h}$$

are lower and upper limit values of the power output of the hydropower station respectively.

Reservoir water level constraint:

$${Z}_{i}^{min} \leq {Z}_{i} \leq {Z}_{i}^{max} ,$$

where Zᵢ is a reservoir water level in the period i; and

$${Z}_{i}^{min} and {Z}_{i}^{max}$$

are minimum and maximum allowable water levels of the reservoir in the period i respectively.

Power output balance constraint:

$${P}_{i}^{h} + {P}_{i}^{w} + {P}_{i}^{s} + {E}_{ws} / i = {P}_{load} ,$$

wherein P_{load} is a power system load demand;
installed capacity constraint:

$$\{ \begin{matrix}0 \leq {V}_{w} \leq {V}_{max}^{w} \\ 0 \leq {V}_{p} \leq {V}_{max}^{p}\end{matrix} , where {V}_{max}^{w} and {V}_{max}^{p}$$

are maximum capacity values of wind turbines and photovoltaic power generation respectively.

Power stability constraint: |Pₐ−Pₐ₋₁|≤ΔPₘₐₓ, where Pₐ is a generating power at time a; Pₐ₋₁ is a generating power at time a−1; ΔPₘₐₓ is a maximum allowable power change of the power system.

The following will describe an exemplary application of the embodiment of the present disclosure in an actual application scenario.

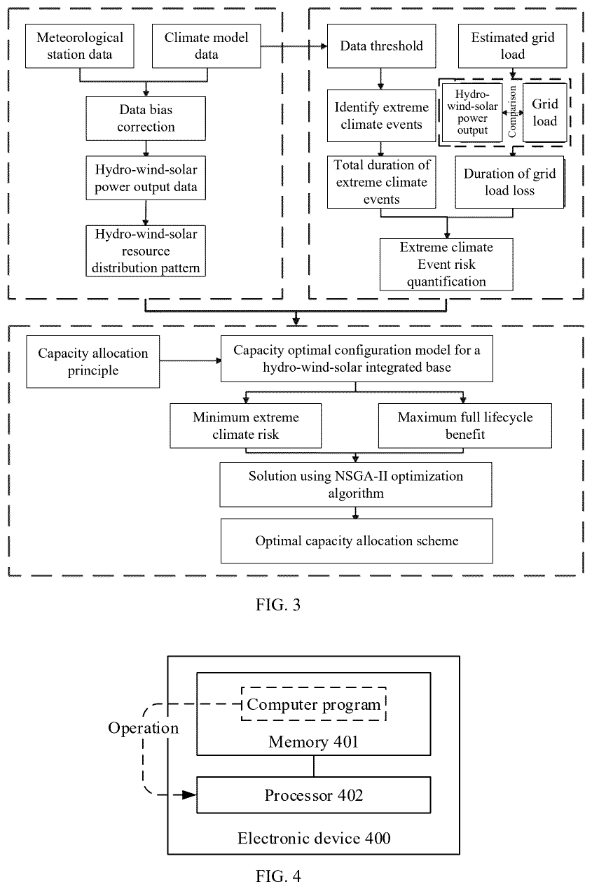

To improve the resilience of the hydro-wind-solar integrated base under climate risks and promote the large-scale development of renewable energy, the present disclosure proposes a flow chart of a capacity optimization method for a hydro-wind-solar integrated base considering extreme climate event risks. As shown in FIG. 3, the specific implementation steps of the method include:
Step S31 Predict hydro-wind-solar power output under a CMIP6 climate model.

First, the server selects the historical and future data of daily wind speed, temperature, solar radiation and precipitation elements under 5 CMIP6 global climate models, and adopts the quantile mapping method (QM) to perform bias correction on the CMIP6 climate model data according to the meteorological and hydrological historical data of meteorological stations to eliminate the difference between model simulation and observation data, make it more consistent with local historical meteorological observation data, and ensure high-precision meteorological element prediction. It should be noted that the CMIP6 climate model data represents the latest global climate model simulation results. The quantile mapping method corrects the cumulative probability distribution of the predicted value according to the cumulative probability distribution of the observed value. In the present disclosure, the formula of the quantile mapping method is as follows:

$${P}_{simP , m}^{cor} = {P}_{simP , m}^{raw} \{ {F}_{obsP , m}^{- 1} [ {F}_{simP , m} ( {P}_{simP , m} ) ] / {P}_{simP , m} \} ;$$

where

$${P}_{simP , m}^{cor}$$

is a corrected prediction sequence;

$${P}_{simP , m}^{raw}$$

is an uncorrected prediction sequence; P_{simP,m} is a specific value in the prediction sequence;

$${F}_{obsP , m}^{- 1}$$

is an inverse function of a cumulative distribution function of measured data in a calibration period, which is used to convert cumulative probability back to an original value; F_{obsP,m} is the cumulative distribution function of the measured data in the calibration period; and F_{simP,m} is the cumulative distribution function of the prediction series in the calibration period.

Based on the corrected data, the server uses the wind power output model and the photovoltaic power output calculation model to predict the wind power output process from 2035 to 2065. The wind power output calculation formula (i.e., the preset wind power output prediction model in the above embodiment) is as follows:

$${P}_{i}^{w} = \{ \begin{matrix}0 , & {v}_{hub , i} \leq {v}_{in} , {v}_{hub , i} \geq {v}_{in} \\ \frac{θ}{{v}_{r}^{3} - {v}_{in}^{3}} {v}_{hub , i}^{3} - \frac{θ}{{v}_{r}^{3} - {v}_{in}^{3}} {v}_{in}^{3} , & {v}_{in} < {v}_{hub , i} < {v}_{r} \\ θ , & {v}_{r} < {v}_{hub , i} < {v}_{out}\end{matrix} ;$$

Where

$${P}_{i}^{w}$$

is a wind power output in the period i; θ is installed capacity of a wind farm; v_{hub,i} is a wind speed at a wind turbine in the period i; and vᵢₙ, vₒᵤₜ, and vᵣ are cut-in wind speed, cut-out wind speed and rated wind speed of the wind turbine respectively.

The solar power output calculation formula (i.e., the preset photovoltaic power output prediction model in the above embodiment) is as follows:

$${P}_{i}^{s} = χ ( \frac{{R}_{i}^{s}}{{R}_{stc}^{s}} ) [ 1 + {α}_{p} ( {T}_{i} - {T}_{s t c} ) ] ;$$

where

$${P}_{i}^{s}$$

is an actual photovoltaic average power output in the ith period; χ is installed capacity of a photovoltaic power station;

$${R}_{i}^{s}$$

is solar radiation intensity in the ith period;

$${R}_{stc}^{s}$$

is solar radiation intensity under standard test conditions; Tᵢ is solar panel temperature; T_{sc} is temperature under the standard test conditions; and aₚ is a temperature power conversion coefficient.

The server can predict the watershed runoff by using a two-parameter monthly water balance model, and then predict the hydropower output by using the hydropower formula. A core idea for the monthly water balance model is to simulate a water balance process of the watershed by considering factors such as precipitation, evaporation and watershed water storage capacity. The two main parameters of the monthly water balance model include parameters C and SC. C represents the water storage capacity or regulation capacity of the watershed, which is related to soil moisture and vegetation coverage of the watershed; SC represents the maximum water storage capacity of watershed, which is closely related to the topography, geology, land use and other characteristics of the watershed. A basic form of the monthly water balance model (i.e., the preset monthly water balance model in the above embodiment) is:

$${Q}_{n} = ( {S}_{n - 1} + {P}_{n} - {E}_{n} ) tanh ( \frac{{S}_{n - 1} + {P}_{n} - {E}_{n}}{S C} ) ;$$

where Qₙ is runoff in an nth month; Sₙ₋₁ is a soil moisture content at the end of the previous month; Pₙ is precipitation in the nth month; Eₙ is actual evaporation in the nth month; and SC is a maximum water storage capacity of watershed.

The hydropower formula (i.e., the preset hydropower output prediction model in the above embodiment) is as follows:

$$N = 9 \text{.81} - η {Q}_{n} H ;$$

where η is an efficiency coefficient of a hydropower station; H is a net water head of the hydropower station.

Step S32 Calculate extreme climate event risks of a hydro-wind-solar integrated base.

Here, the server determines thresholds for data such as wind speed and solar radiation based on 2035-2065 CMIP6 climate model wind speed, temperature, solar radiation, and precipitation data after bias correction, which are used to identify “no wind”, “no light”, and “no wind and no light” events. The server calculates the occurrence frequency and duration of different extreme climate events. The calculation formulas for the occurrence frequency and duration of different extreme climate events are as follows:
the calculation formula of the occurrence frequency is:

$$F = {{\sum }^{l}}_{a = 1} A ( a ) ,$$

$$A ( a ) = \{ \begin{matrix}1 , & S ( a ) \geq {S}_{m} OR S ( a ) < {S}_{n} \\ 0 , & {S}_{n} \leq S ( a ) < {S}_{m}\end{matrix} ;$$

where A(a) is a number of occurrences of the extreme climate events meeting a corresponding threshold within a corresponding period; 1 is a total statistical duration; S(a) is an actual value of the target wind speed, the target temperature, the target solar radiation or the target precipitation at time a; Sₘ is an upper limit value for judging whether a current climate at time a is the extreme climate event; Sₙ is a lower limit value for judging whether the current climate at time a is the extreme climate event; and F is the occurrence frequency of the corresponding extreme climate event; and
the calculation formula of the duration is: Uₖ=a₂(k)−a₁(k); where Uₖ is a duration of a kth extreme climate event; a₁(k) is a start time of the kth extreme climate event; a₂(k) is an end time of the kth extreme climate event.

Then, the server predicts a long-series grid demand (grid load) through a linear trend method, calculates a load loss risk by comparing the power output (i.e., the future hydropower output, future wind power output and future solar power output in the above embodiment) and the load at the corresponding time, and combines the occurrence frequency and duration of the extreme climate events to identify different types of the extreme climate events and calculate their occurrence probabilities, so as to achieve the purpose of quantifying extreme climate event risks.

Finally, the server establishes a risk assessment model for the extreme climate events by combining climate data, historical data and identification of the extreme climate events. The occurrence frequency of different extreme climate events (such as high temperature, drought, cold wave, etc.) is analyzed, and the extreme climate event risks are estimated through an extreme value theory (EVT).

It should be noted that the extreme value theory is an important branch of statistics, mainly focusing on the probability distribution and properties of extreme climate events. EVT can accurately measure the value at extreme climate event risks with tail distribution, and has been widely used in the field of natural disaster prediction.

In some embodiments, a load loss risk refers to a risk that a power system cannot meet user demand due to insufficient power generation output or excessive grid load.

In the present disclosure, the load loss risk is calculated by comparing future hydropower output, future wind power output and future solar power output with the load, considering volatility of power generation output and the change of grid load.

Step S33 Perform multi-objective capacity optimal configuration of hydro-wind-solar integrated base considering extreme climate event risks.

First, the server establishes capacity optimal configuration principles, including feasibility rules, economic rules, volatility rules and load matching rules. The feasibility rules can be understood as ensuring that the designed system is technically and environmentally implementable, including full utilization of resources, assessment of environmental impacts and verification of technical feasibility; the economic rules can be understood as ensuring that the design and operation of the system have good economic benefits, and can minimize costs and maximize benefits; the volatility rules can be understood as considering the uncertainty and volatility of renewable energy output, and needing to balance supply and demand through appropriate design; the load matching rules can be understood as ensuring that the output of the power generation system can effectively meet the user's power demand and avoid supply-demand imbalance, etc. Then, the server establishes a multi-objective capacity optimal configuration model for a hydro-wind-solar integrated base considering climate event risks. At the same time, the server establishes the first objective function, that is, minimizing the extreme climate event risk, and quantifies the operation risk caused by extreme climate events through a comprehensive risk rate.

The first objective function is:

$$min {f}_{1} = {\sum }_{i = 1}^{I} {M}_{i} \cdot ( {R}_{d} + {R}_{h} + … + {R}_{e} ) ;$$

where: I is a number of scenario modes; i is a period; Mᵢ is an occurrence frequency of the extreme climate events leading to reduced power output in the period R_{d}, Rₕ, . . . and R_{c} are probabilities of low power output operation of hydro-wind-solar power under different extreme climate event conditions respectively;

The server establishes an objective function of maximizing life cycle benefit, that is, the second objective function is:

$$max {f}_{2} = {\sum }_{t = 0}^{T} \frac{( {S}_{ele} + {S}_{subsidy} + {S}_{carbon} ) - ( {C}_{ope} + {C}_{main} + {C}_{sto} )}{{( 1 + r )}^{t}} - {I}_{o} ;$$

where t is a period; T is a project life cycle; r is a discount rate; Sₑₗₑ is an electricity sales revenue; S_{subsidy} is a government subsidy revenue; Sₑₗₑ is an electricity sales revenue; S_{subsidy} is a government subsidy revenue; S_{carbon} is a carbon trading revenue; Cₒₚₑ is a cost for power station operation; Cₘₐᵢₙ is a cost for power station facility maintenance; Cₛₜₒ is a cost for an energy storage system; and Iₒ is a cost for wind-solar-hydro storage integrated construction.

Then, the server constructs constraint conditions for the first objective function and the second objective function, and the constraint conditions include:
wind power output constraint:

$$0 \leq {P}_{i}^{w} \leq {P}_{max}^{w} ; where {P}_{i}^{w}$$

is the wind power output in the period i; and

$${P}_{max}^{w}$$

is an upper limit value of the wind power output.

Solar power output constraint:

$$0 \leq {P}_{i}^{s} \leq {P}_{max}^{s} ;$$

where is

$${P}_{i}^{s}$$

the solar power output in the period i; and

$${P}_{max}^{s}$$

is an upper limit value of the solar power output.

Curtailment rate constraint: E_{ws}/E<σ; where E is a total wind-solar power generation in the period; E_{ws} is a total curtailed wind-solar power in the period; and σ is an allowable wind-solar curtailment rate of the system.

Hydropower station power output constraint:

$${P}_{min}^{h} \leq {P}_{i}^{h} \leq {P}_{max}^{h} , where {P}_{i}^{h}$$

is a hydropower output in the period i; and

$${P}_{min}^{h} and {P}_{max}^{h}$$

are lower and upper limit values of the power output of the hydropower station respectively.

Reservoir water level constraint:

$${Z}_{i}^{min} \leq {Z}_{i} \leq {Z}_{i}^{max} ,$$

where Z is a reservoir water level in the period i; and

$${Z}_{i}^{min} and {Z}_{i}^{max}$$

are minimum and maximum allowable water levels of the reservoir in the period i respectively. Power output balance constraint:

$${P}_{i}^{h} + {P}_{i}^{w} + {P}_{i}^{s} + {E}_{ws} / i = {P}_{load} ,$$

where P_{load} is a power system load demand.

Installed capacity constraint:

$$\{ \begin{matrix}0 \leq {V}_{w} \leq {V}_{max}^{w} \\ 0 \leq {V}_{p} \leq {V}_{max}^{p}\end{matrix} ,$$

where

$${V}_{max}^{w} and {V}_{max}^{p}$$

are maximum capacity values of wind turbines and photovoltaic power generation respectively.

Power stability constraint: |Pₐ−Pₐ₋₁|ΔPₘₐₓ, where Pₐ is a generating power at time a; Pₐ₋₁ is a generating power at time a−1; ΔPₘₐₓ is a maximum allowable power change of the power system.

In the embodiment of the present disclosure, the server uses a second-generation non-dominated sorting genetic algorithm (NSGA-II) to solve a Pareto solution set of a mathematical model of the hydro-wind-solar integrated operation system based on typical hydro-wind-solar power output data. Further, based on a model output scheme, an Analytic Hierarchy Process (AHP) is used to account for the preferences of different decision-makers and formulate various optimal capacity allocation schemes. The AHP divides various complex indicators into ordered and correlated indicators by establishing a multi-level structure. By conducting pairwise comparisons of the importance among indicator factors, the AHP optimizes a weight assignment process among indicators and increases the objectivity and logic of decision-making judgments among a plurality of indicators. Finally, by comparing the capacity ratios of other hydro-wind-solar integrated projects, the degree of risk reduction and benefit improvement of the capacity optimal configuration in this study is calculated to achieve an objective of optimal configuration.

The NSGA-II algorithm is renowned for its efficiency in handling large populations and ability to maintain solution diversity. The NSGA-II algorithm uses a fast non-dominated sorting method, elitism, and a crowding distance mechanism to ensure a well-distributed Pareto front. The basic steps for the implementation of the NSGA-II algorithm include: initializing the population, fitness function evaluation, non-dominated sorting, calculating crowding distance, selecting parents for crossover, crossover/mutation operations, and iteration.

It should be noted that in the embodiment of the present disclosure, if the above-mentioned capacity optimization method for a hydro-wind-solar integrated base considering extreme climate event risks is implemented in the form of software function modules and sold or used as an independent product, it can also be stored in a computer-readable storage medium. Understood as such, the essence of the technical solution of the embodiment of the present disclosure or the part that contributes to related technologies can be embodied in the form of a software product. The computer software product is stored in a storage medium and includes several instructions to cause a terminal to execute all or part of the methods described in the various embodiments of the present disclosure. The above-mentioned storage medium includes: USB flash drives, portable hard disks, Read Only Memory (ROM), magnetic disks, optical discs, and other media that can store program codes. As such, the embodiment of the present disclosure is not limited to any specific combination of hardware and software.

Correspondingly, an embodiment of the present disclosure provides a capacity optimization device for a hydro-wind-solar integrated base considering extreme climate event risks. FIG. 4 is a structural schematic diagram of a composition of a capacity optimization device for a hydro-wind-solar integrated base considering extreme climate event risks according to an embodiment of the present disclosure. As shown in FIG. 4, a capacity optimization device for a hydro-wind-solar integrated base 400 considering extreme climate event risks at least includes: a processor 401 and a computer-readable storage medium 402 configured to store executable instructions, where the processor 401 generally controls the overall operation of the capacity optimization device for the hydro-wind-solar integrated base 400 considering extreme climate event risks. The computer-readable storage medium 402 is configured to store instructions and applications executable by the processor 401, and can also cache data to be processed or processed by the processor 401 and various modules in the capacity optimization device for the hydro-wind-solar integrated base 400 considering extreme climate event risks, which can be implemented through flash memory (FLASH) or Random Access Memory (RAM).

An embodiment of the present disclosure provides a storage medium storing executable instructions, where executable instructions are stored. When the executable instructions are executed by a processor, they will cause the processor to execute the method provided by the embodiment of the present disclosure, for example, the method shown in FIG. 2.

In some embodiments, the storage medium may be a computer-readable storage medium, such as Ferromagnetic Random Access Memory (FRAM), Read Only Memory (ROM), Programmable Read Only Memory (PROM), Erasable Programmable Read Only Memory (EPROM), Electrically Erasable Programmable Read Only Memory (EEPROM), flash memory, magnetic surface memory, optical discs, or Compact Disk-Read Only Memory (CD-ROM); it may also be various devices including one or any combination of the above-mentioned memories.

In some embodiments, executable instructions may take the form of programs, software, software modules, scripts, or code, written in any form of programming language (including compiled or interpreted languages, or declarative or procedural languages), and may be deployed in any form, including as stand-alone programs or as modules, components, subroutines, or other units suitable for use in a computing environment.

As an example, executable instructions may, but need not, correspond to files in a file system, and may be stored as part of a file that holds other programs or data, for example, in one or more scripts in Hyper Text Markup Language (HTML) documents, in a single file dedicated to the program in question, or in a plurality of coordinated files (e.g., files storing one or more modules, subroutines, or code sections). As an example, executable instructions may be deployed to be executed on one electronic device, on a plurality of electronic devices located at one site, or on a plurality of electronic devices distributed across a plurality of sites and interconnected via a communication network.

The above are merely embodiments of the present disclosure and are not intended to limit the protection scope of the present disclosure. Any modifications, equivalent substitutions, improvements and the like made within the spirit and scope of the present disclosure shall be included within the protection scope of the present disclosure.

It should be understood that references throughout the description to “one embodiment” or “an embodiment” mean that a particular feature, structure, or characteristic related to the embodiment is included in at least one embodiment of the present disclosure. Therefore, the phrases “in one embodiment” or “in an embodiment” appearing throughout the description are not necessarily intended to refer to the same embodiment. Furthermore, these specific features, structures, or characteristics may be combined in any suitable manner in one or more embodiments. It should be understood that, in various embodiments of the present disclosure, the sequence numbers of the above-mentioned processes do not imply the order of execution; instead, the execution order of each process shall be determined based on its function and inherent logic, and shall not constitute any limitation on the implementation process of the embodiments of the present disclosure. The above-mentioned serial numbers of the embodiments of the present disclosure are merely for the purpose of description and do not represent the advantages and disadvantages of the embodiments.

It should be noted that, in this document, the terms “include,” “comprise,” or any other variations thereof are intended to cover a non-exclusive inclusion, such that a process, method, or apparatus including a series of elements not only includes those elements but also includes other elements not expressly listed, or elements inherent to such a process, method, or apparatus. Without further limitations, an element defined by the phrase “includes one . . . ” does not exclude the presence of additional identical elements in the process, method, article, or apparatus that includes the element. In the several embodiments provided by the present disclosure, it should be understood that the disclosed devices and methods may be implemented in other ways. The device embodiments described above are merely illustrative. For example, the division of the units is merely a logical function division, and there may be other division methods in actual implementation: multiple units or components may be combined, or integrated into another system, or some features may be omitted or not performed.

The foregoing are merely specific implementations of the present disclosure, but the protection scope of the present disclosure is not limited thereto. Any person skilled in the art can easily conceive of changes or substitutions within the technical scope disclosed by the present disclosure, which shall all be encompassed within the protection scope of the present disclosure. Therefore, the protection scope of the present disclosure shall be based on the protection scope defined by the appended claims.

1. A computer-implemented capacity optimization method for a hydro-wind-solar integrated base considering extreme climate event risks, comprising:
acquiring, by an acquisition device, a plurality of CMIP6 global climate model data from a sixth phase of a global climate model intercomparison project and meteorological and hydrological historical data, wherein the CMIP6 global climate model data comprise historical climate model data and future climate model data;
performing, by a correction device, bias correction on the future climate model data using a quantile mapping method based on a difference between the historical climate model data and the meteorological and hydrological historical data to obtain corrected climate model data, wherein the corrected climate model data comprises target wind speed, target temperature, target solar radiation, and target precipitation;
predicting, by a prediction device, future hydro-wind-solar power output based on the corrected climate model data, wherein the predicting comprises:
predicting future wind power output using a preset wind power output prediction model based on the target wind speed, wherein the preset wind power output prediction model calculates power output based on a cut-in wind speed, a cut-out wind speed, and a rated wind speed of a wind turbine;
predicting future solar power output using a preset photovoltaic power output prediction model based on the target temperature and the target solar radiation, wherein the preset photovoltaic power output prediction model calculates power output based on solar radiation intensity and a solar panel temperature; and
predicting future hydropower output by predicting watershed runoff using a preset monthly water balance model based on the target precipitation, and predicting the future hydropower output using a preset hydropower output prediction model based on the watershed runoff,
determining, by a determination device, extreme climate events based on the corrected climate model data, wherein determining the extreme climate events comprises comparing the target wind speed, the target temperature, the target solar radiation, and the target precipitation with respective preset thresholds;
determining, by the determination device, extreme climate event risks, that is, a ratio of a grid load loss duration during an occurrence of the extreme climate event to a total duration of the extreme climate event, based on predicted long-series grid load and the future hydro-wind-solar power output during occurrence of the extreme climate events; and
constructing, by the determination device, a multi-objective capacity optimal configuration model for the hydro-wind-solar integrated base considering extreme climate event risks with objectives of minimizing extreme climate event risks and maximizing life cycle benefit, and determining a multi-objective capacity optimal configuration strategy for the hydro-wind-solar integrated base by solving the multi-objective capacity optimal configuration model under a set of power system physical operation constraints;
wherein a first objective function for minimizing the extreme climate event risks is:
$$min {f}_{1} = {\sum }_{i = 1}^{I} {M}_{i} \cdot ( {R}_{d} + {R}_{h} + … + {R}_{c} ) ;$$
wherein: I is a number of scenario modes; i is a period; Mᵢ is an occurrence frequency of the extreme climate events leading to reduced power output in the period i; R_{d}, Rₕ, . . . and R_{c} are probabilities of low power output operation of hydro-wind-solar power under different extreme climate event conditions respectively;
a second objective function for maximizing the life cycle benefit is:
$$max {f}_{2} = {\sum }_{t = 0}^{T} \frac{( {S}_{ele} + {S}_{subsidy} + {S}_{carbon} ) - ( {C}_{ope} + {C}_{main} + {C}_{sto} )}{{( 1 + r )}^{t}} - {I}_{o} ;$$
wherein: t is a period; T is a project life cycle; r is a discount rate; Sₑₗₑ is an electricity sales revenue; S_{subsidy} is a government subsidy revenue; S_{carbon} is a carbon trading revenue; Cₒₚₑ is a cost for power station operation; Cₘₐᵢₙ is a cost for power station facility maintenance; Cₛₜₒ is a cost for an energy storage system; and Iₒ is a cost for wind-solar-hydro storage integrated construction.

2. The method according to claim 1, wherein the performing bias correction on the future climate model data based on the historical climate model data and the meteorological and hydrological historical data to obtain corrected climate model data comprises:
performing data comparison between the historical climate model data and the meteorological and hydrological historical data to obtain meteorological data differences; and
performing bias correction on the future climate model data using a quantile mapping method based on the meteorological data differences to obtain the corrected climate model data.

3. The method according to claim 1,
wherein the preset wind power output prediction model is:
$${P}_{i}^{w} = \{ \begin{matrix}0 , & {v}_{hub , i} \leq {v}_{in} , {v}_{hub , i} \geq {v}_{in} \\ \frac{θ}{{v}_{r}^{3} - {v}_{in}^{3}} {v}_{hub , i}^{3} - \frac{θ}{{v}_{r}^{3} - {v}_{in}^{3}} {v}_{in}^{3} , & {v}_{in} \geq {v}_{hub , i} < {v}_{r} \\ θ , & {v}_{r} < {v}_{hub , i} < {v}_{out}\end{matrix} ;$$
wherein
$${P}_{i}^{w}$$
is a wind power output in the period i; θ is installed capacity of a wind farm; v_{hub,j} is a wind speed at a wind turbine in the period i; and vᵢₙ, vₒᵤₜ, and vᵣ are cut-in wind speed, cut-out wind speed and rated wind speed of the wind turbine respectively;
the preset photovoltaic power output prediction model is:
$${P}_{i}^{s} = χ ( \frac{{R}_{i}^{s}}{{R}_{stc}^{s}} ) [ 1 + {α}_{p} ( {T}_{i} - {T}_{stc} ) ] ;$$
wherein
$${P}_{i}^{s}$$
is an actual photovoltaic average power output in the ith period; χ is installed capacity of a photovoltaic power station;
$${R}_{i}^{s}$$
is solar radiation intensity in the ith period;
$${R}_{stc}^{s}$$
is solar radiation intensity under standard test conditions; Tᵢ is solar panel temperature; T_{stc} is temperature under the standard test conditions; and aₚ is a temperature power conversion coefficient;
the preset monthly water balance model is:
$${Q}_{n} = ( {S}_{n - 1} + {P}_{n} - {E}_{n} ) tanh ( \frac{{S}_{n - 1} + {P}_{n} - {E}_{n}}{SC} ) ;$$
wherein Qₙ is runoff in an nth month; Sₙ₋₁ is a soil moisture content at an end of a previous month; Pₙ is precipitation in the nth month; Eₙ is actual evaporation in the nth month; and SC is a maximum water storage capacity of watershed; and
the preset hydropower output prediction model is: N=9.81ηQₙH; wherein q is an efficiency coefficient of a hydropower station; and H is a net water head of the hydropower station.

4. The method according to claim 3, wherein the determining extreme climate events based on the corrected climate model data comprises:
determining wind speed threshold, temperature threshold, solar radiation threshold and precipitation threshold based on the target wind speed, the target temperature, the target solar radiation and the target precipitation; and
determining the extreme climate events based on the wind speed threshold, the temperature threshold, the solar radiation threshold and the precipitation threshold.

5. The method according to claim 4, further comprising:
calculating the occurrence frequency and the duration of the extreme climate events;
the determining extreme climate event risks based on predicted long-series grid load and the future hydro-wind-solar power output during occurrence of the extreme climate events comprises:
determining the extreme climate event risks based on the occurrence frequency, the duration, the predicted long-series grid load and the future hydro-wind-solar power output;
wherein the calculation formula of the occurrence frequency is:
$$F = {\sum }_{a = 1}^{l} A ( a ) , A ( a ) = \{ \begin{matrix}1 , & S ( a ) \geq {S}_{m} OR S ( a ) < {S}_{n} \\ 0 , & {S}_{n} \leq S ( a ) < {S}_{m}\end{matrix} ;$$
wherein A(a) is a number of occurrences of the extreme climate events meeting a corresponding threshold within a corresponding period; 1 is a total statistical duration; S(a) is an actual value of the target wind speed, the target temperature, the target solar radiation or the target precipitation at time a; Sᵢₙ is an upper limit value for judging whether a current climate at time a is the extreme climate event; Sₙ is a lower limit value for judging whether the current climate at time a is the extreme climate event; and F is the occurrence frequency of the corresponding extreme climate event; and
the calculation formula of the duration is: Uₖ=a₂(k)−a₁(k); wherein Uₖ is a duration of a kth extreme climate event; a₁(k) is a start time of the kth extreme climate event; a₂(k) is an end time of the kth extreme climate event.

6. The method according to claim 1, further comprising:
constructing constraint conditions for the first objective function and the second objective function;
the constraint conditions comprise:
wind power output constraint:
$$0 \leq {P}_{i}^{w} \leq {P}_{max}^{w} ;$$
wherein
$${P}_{i}^{w}$$
is the wind power output in the period i; and
$${P}_{max}^{w}$$
is an upper limit value of the wind power output;
solar power output constraint:
$$0 \leq {P}_{i}^{s} \leq {P}_{max}^{s} ;$$
wherein
$${P}_{i}^{s}$$
is the solar power output in the period i; and
$${P}_{max}^{s}$$
is an upper limit value of the solar power output;
curtailment rate constraint: E_{ws}/E<σ; wherein E is a total wind-solar power generation in the period; E_{ws} is a total curtailed wind-solar power in the period; and σ is an allowable wind-solar curtailment rate of the system;
hydropower station power output constraint:
$${P}_{min}^{h} \leq {P}_{i}^{h} \leq {P}_{max}^{h} ,$$
wherein
$${P}_{i}^{h}$$
is a hydropower output in the period i; and
$${P}_{min}^{h} and {P}_{max}^{h}$$
are lower and upper limit values of the power output of the hydropower station respectively;
reservoir water level constraint:
$${Z}_{i}^{min} \leq {Z}_{i} \leq {Z}_{i}^{max} ,$$
wherein Zᵢ is a reservoir water level in the period i; and
$${Z}_{i}^{min} and {Z}_{i}^{max}$$
are minimum and maximum allowable water levels of the reservoir in the period i respectively;
power output balance constraint:
$${P}_{i}^{h} + {P}_{i}^{w} + {P}_{i}^{s} + {E}_{w s} / i = {P}_{load} ,$$
wherein P_{load} is a power system load demand;
installed capacity constraint:
$$\{ \begin{matrix}0 \leq {V}_{w} \leq {V}_{max}^{w} \\ 0 \leq {V}_{p} \leq {V}_{max}^{p}\end{matrix} ,$$
wherein
$${V}_{max}^{w} and {V}_{max}^{p}$$
are maximum capacity values of wind turbines and photovoltaic power generation respectively; and
power stability constraint: |Pₐ−Pₐ₋₁|≤ΔPₘₐₓ, wherein Pₐ is a generating power at time a; Pₐ₋₁ is a generating power at time a−1; ΔPₘₐₓ is a maximum allowable power change of the power system.
